(19) United States
(12) Patent Application Publication
(10) Pub. No.: US 2012/0156394 A1
(43) Pub. Date: Jun. 21, 2012

(54) DISCHARGE SURFACE TREATMENT

(75) Inventors: Hiroki Yoshizawa, Tokyo (JP); Mitsutoshi Watanabe, Tokyo (JP); Hidemi Ukai, Tokyo (JP); Kyouhei Nomura, Tokyo (JP); Yukihiro Shimoda, Tokyo (JP); Hiroyuki Ochiai, Tokyo (JP); Keiji Kubushiro, Tokyo (JP)

(73) Assignee: IHI Corporation, Tokyo (JP)

(21) Appl. No.: 13/392,326

(22) PCT Filed: Sep. 2, 2010
(86) PCT No.: PCT/JP10/65026

§ 371 Date: Feb. 24, 2012

(30) Foreign Application Priority Data
Sep. 3, 2009 (JP) 2009-203629

(51) Int. Cl. C23C 14/00; B22F 3/12; B05C 9/08

(52) U.S. Cl. 427/580; 118/620; 419/10

(57) ABSTRACT

An electrode used in combination with an electric spark machine for surface treatment, is comprised of a mixed powder including a powder of aluminum at a ratio of 5-18 weight % to the total of the mixed powder or a powder of any metal selected from the group consisting of nickel, cobalt, and iron at a ratio of 5-40 weight % to the total of the mixed powder and a powder of titanium hydride, wherein the mixed powder is formed by molding and sintering into a structure so dimensioned as to be incorporated in the electric spark machine as an electrode therefor.

### TECHNICAL FIELD

The present invention relates to an electrode for forming a coating on a subject body by using electric discharge, a production method therefor, and a method for forming a coating therewith.

### BACKGROUND ART

To bring a non-exhaustible electrode close to a subject body in oil or in the air and then generate electric discharge therebetween may result in machining of the subject body. This art is generally referred to as electric spark machining, which enables precise and complex machining. Under considerable conditions, e.g. a condition in which an exhaustible electrode such as a green pellet is used instead of a non-exhaustible electrode, wear of the electrode preferentially occurs instead of machining of the subject body. Constituents of the electrode or its reaction products then cover a region opposed to the electrode on the subject body, thereby enabling surface treatment of the subject body. This art is sometimes referred to as “discharge surface treatment”.

When the discharge surface treatment is executed in a liquid including hydrocarbon such as mineral oil, substances discharged out of an electrode and carbon often develop chemical reactions, thereby enabling formation of a coating consisting of carbides. Among many carbides, titanium carbide is very hard. Thus such coatings are promising in view of various industrial uses. A related art is disclosed in an International Patent Publication WO01/005545.

### DISCLOSURE OF INVENTION

It is possible to successfully form a coating of titanium carbide about 20-30 micrometers thick by means of discharge surface treatment. The present inventors had tried growth of a thicker titanium carbide coating in order to seek further improvement of properties and then found that formation of a titanium carbide coating with a thickness greater than the aforementioned thickness is difficult. The present invention has been achieved in view of this problem and is intended to provide a method for forming thicker coatings including titanium carbide by discharge surface treatment and electrodes therefor.

According to a first aspect of the present invention, an electrode used in combination with an electric spark machine for surface treatment is comprised of a mixed powder including a powder of aluminum at a ratio of 5-18 weight % to the total of the mixed powder or a powder of any metal selected from the group consisting of nickel, cobalt, and iron at a ratio of 5-40 weight % to the total of the mixed powder, and a powder of titanium hydride, wherein the mixed powder is formed by molding and sintering into a structure so dimensioned as to be incorporated in the electric spark machine as an electrode therefor.

According to a second aspect of the present invention, a method of production of an electrode used in combination with an electric spark machine, is obtaining a mixed powder by mixing a powder of aluminum at a ratio of 5-18 weight % to the total of the mixed powder or a powder of any metal selected from the group consisting of nickel, cobalt, and iron at a ratio of 5-40 weight % to the total of the mixed powder with a powder of titanium hydride; and molding and sintering the mixed powder to form a structure so dimensioned as to be incorporated in the electric spark machine as an electrode therefor.

According to a third aspect of the present invention, a method of surface treatment of a subject body by an electric spark machine is comprised of obtaining a mixed powder by mixing a powder of aluminum at a ratio of 5-18 weight % to the total of the mixed powder or a powder of any metal selected from the group consisting of nickel, cobalt, and iron at a ratio of 5-40 weight % to the total of the mixed powder with a powder of titanium hydride, obtaining a molded body by molding and sintering the mixed powder to form a structure so dimensioned as to be incorporated in the electric spark machine as an electrode therefor, incorporating the molded body into the electric spark machine, and generating a coating on the subject body by bringing the molded body close to the subject body in an oil and generating electric discharge therebetween.

### BRIEF DESCRIPTION OF DRAWINGS

FIG. 1 is a schematic drawing depicting a microstructure of an electrode according to an embodiment of the present invention.

FIG. 2 is a schematic drawing depicting an electric spark machine used in discharge surface treatment according to the embodiment.

FIG. 3 is a schematic drawing depicting a mixer used in production of the electrode according to the embodiment of the present invention.

FIG. 4 is a schematic drawing depicting a step in the production of the electrode according to the embodiment.

FIG. 5 is an example of a profile of voltage and current applied to the electric spark machine.

FIG. 6 shows an example of a subject body of discharge surface treatment, which depicts an elevational view of a turbine rotor blade.

FIG. 7 is a schematic drawing depicting a microstructure of a coating formed by the discharge surface treatment.

### BEST MODE FOR CARRYING OUT THE INVENTION

Certain embodiments will be described hereinafter with reference to the appended drawings.

In discharge surface treatment used is an exhaustible electrode having a property by which it gradually wears in electric discharge. As a material for the exhaustible electrode, a powder including an electrically conductive substance is preferably used. The powder may be totally of any electrically conductive substance, or alternatively be a mixed powder of a powder of an electrically conductive substance and a powder of any other substance, such as a proper ceramic. Further, as the electrically conductive substance, a mixed powder of two or more electrically conductive substances may be used.

If a titanium hydride (TiH₂) is selected as the electrically conductive material and the discharge surface treatment is executed in a liquid including hydrocarbon such as a mineral oil, a coating including titanium carbide is obtained as discussed above. According to studies by the present inventors, when electric discharge is repeatedly applied so as to grow the coating with a thickness beyond 20-30 micrometers, it is observed that the growth rate extremely gets smaller. If electric discharge is further repeated, no coating growth is observed. Although the cause of this phenomenon has not been sufficiently made clear, the present inventors currently infer that, when the coating grows to be relatively thick, wearing of the coating occurs as well as it grows and then wearing and growth balance. Thus it can be inferred that, if additives to prevent the coating from wearing are in advance made contained in the electrode, thicker growth of a coating including titanium carbide may be possible.

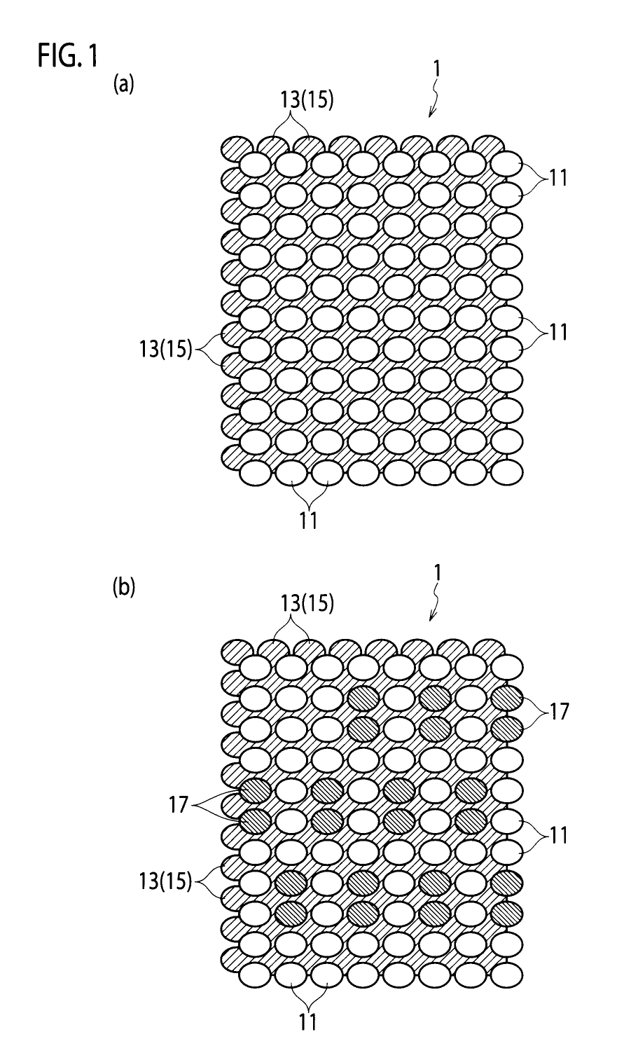

Referring to FIG. 1(a), in the present embodiment, the electrode is produced by utilizing a mixed powder of a powder 11 of titanium hydride and a powder 13 of aluminum. This titanium hydride, as a result of discharge surface treatment, forms titanium carbide and then becomes incorporated in the coating, thereby giving hardness to the coating. Aluminum, as a result of discharge surface treatment, becomes incorporated in the coating, thereby giving deformability to the coating. In parallel, aluminum changes part of titanium hydride into titanium, which becomes incorporated in the coating, thereby further giving deformability to the coating. A coating with hardness but short of deformability will be vulnerable to local thermal shock given in the process of discharge surface treatment and be therefore likely to wear as it grows. In contrast, a coating with deformability given by aluminum can be resistant to thermal shock and is therefore capable of growing thicker.

The amount of addition of the powder of aluminum is over 0 weight % to the total of the mixed powder because greater amounts lead to better deformability, preferably over 5 weight %, and more preferably over 10 weight %. Moreover, in light of exhaustibility of the electrode after sintering, non-excessive amounts of addition of aluminum are beneficial. Thus the amount is less than 30 weight % to the total of the mixed powder, preferably less than 18 weight %, and more preferably less than 15 weight %.

Alternatively, instead of the powder 13 of aluminum, or in addition thereto, a powder 15 of any metal of the iron group may be mixed therein. The metal of the iron group is, in accordance with the well-known definition, any of nickel, cobalt, and iron. Any single element, or a mixture, of nickel, cobalt, and iron may be applicable. These iron group metals, as with aluminum, give deformability to the coating and therefore contribute to thicker growth of the coating.

The amount of addition of the powder of the iron group metal is over 0 weight % to the total of the mixed powder because greater amounts lead to better deformability, preferably over 5 weight %, and more preferably over 10 weight %. Moreover, in light of exhaustibility of the electrode after sintering, non-excessive amounts of addition of the amount of the iron group metal are beneficial. Thus the amount is less than 60 weight % to the total of the mixed powder, preferably less than 40 weight %.

In addition, a powder 17 of titanium carbide may be mixed therein as shown in FIG. 1(b). The powder, if mixed, is preferably over 0 weight % to the total of the mixed powder, and less than 30 weight % in light of retention of sufficient electrical conductivity of the electrode. Inclusion of any component which materially affects the basic and novel characteristics of the present invention is essentially excluded except it is an unavoidable impurity, whereas inclusion of any component which does not materially affect the basic and novel characteristics is permissible.

The particle size may be, although not particularly limited, 10 micrometers or less and more preferably 3 micrometers or less for example.

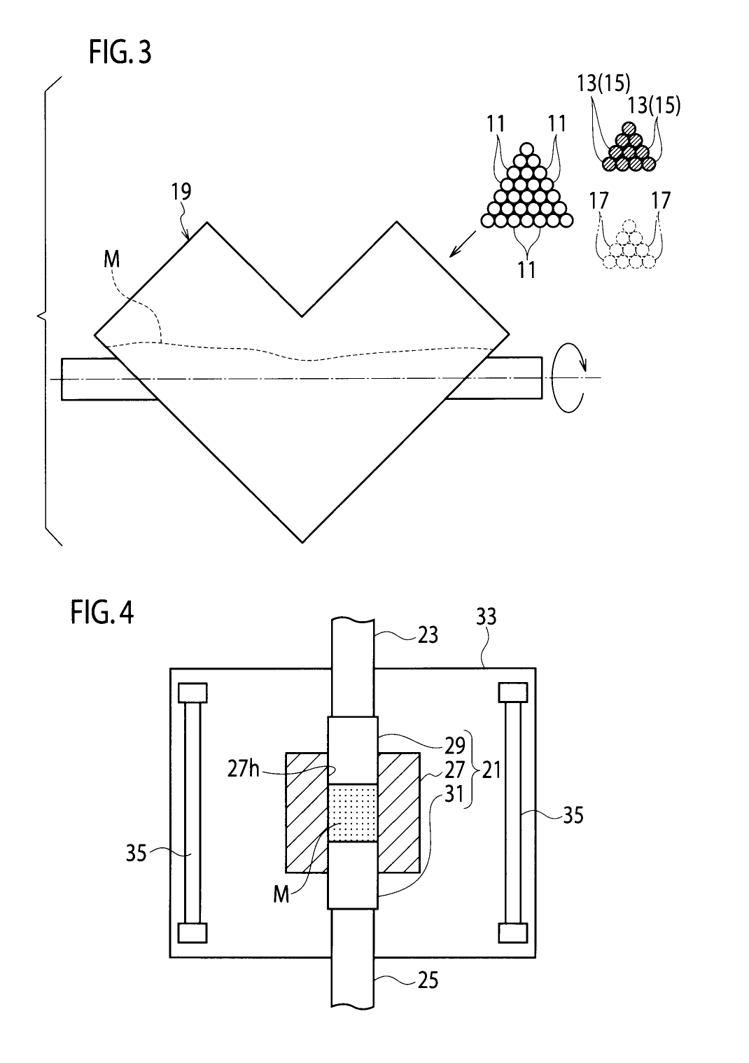

The respective powders are mixed together by utilizing any proper mixer. FIG. 3 depicts an example of such a mixer, which is generally referred to as “V-blender”. The V-blender 19 is comprised of a pair of hollow cylinders joined together in a V-letter shape, and is driven by a proper motor to rotate about an axis shown by a dashed line in the drawing. Because the V-blender 19, by means of its rotation, applies force by which the powder in the cylinders departs and force by which the powder gathers together alternately to the powder, and simultaneously stirs the powder, it is preferably suited for uniform mixing. Of course, any other proper mixer can be used.

The powder 11 of titanium hydride and the powder 13 of aluminum (alternatively, instead of, or in addition thereto, the powder 15 of an iron-group metal), and the powder 17 of titanium carbide added in some cases, are prepared in a way described above and thereafter put in the V-letter-shape cylinder. Then the V-letter-shape cylinder is made to rotate by means of a proper motor, so that the powder is uniformly mixed and then a mixed powder M is obtained.

Preferably the mixed powder M is subject to hot pressing. A hot pressing device is, as shown in FIG. 4, comprised of a mold 21, which is comprised of a die 27 supporting its side and punches 29, 31 supporting its ends. A space enclosed by the die 27 and the punches 29, 31 is so dimensioned as to have a shape, a molded powder by which is applicable to an electrode for the electric spark machine. Alternatively, it is possible to first form it in a shape different from the electrode and next finish it after sintering so as to produce a shape as an electrode. The mixed powder M is filled in the space enclosed by the die 27 and the punches 29, 31. While the die 27 is placed in a fixed state, the punches 29, 31 are movable and driven by rams 23, 25 respectively, thereby giving pressure to the mixed powder M in the mold 21. The hot pressing device is further comprised of a vacuum furnace 33 with a heater 35, and the mixed powder M is heated in a pressurized state, thereby executing molding and sintering simultaneously. A molded body obtained in a step as described above has a structure so dimensioned as to be incorporated in the electric spark machine as its electrode, and is also adapted for electric surface treatment as it has proper exhaustibility.

Instead of hot pressing, hot isostatic pressing (HIP) may be executed. Alternatively, sintering in a vacuum furnace after proper molding may be executed. For the purpose of molding, injection molding or slurry pouring may be used.

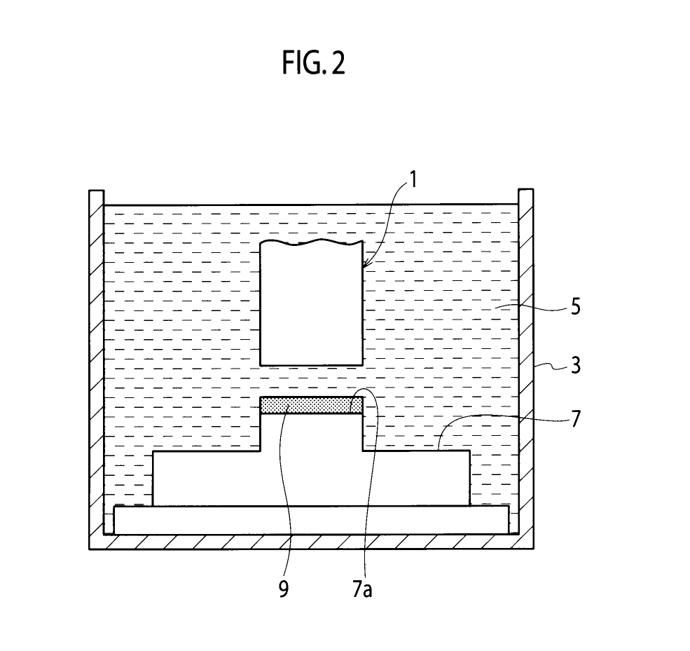

The aforementioned molded body is, as shown in FIG. 2, incorporated into the electric spark machine as its electrode 1. A processing bath 3 of the electric spark machine is filled with proper oil 5 such as mineral oil and the electrode 1 along with a subject body 7 is sunk into the oil 5. The electrode 1 is next brought close to the subject body 7 and electric power is intermittently applied from an external power source to generate electric discharge therebetween, thereby executing electric surface treatment.

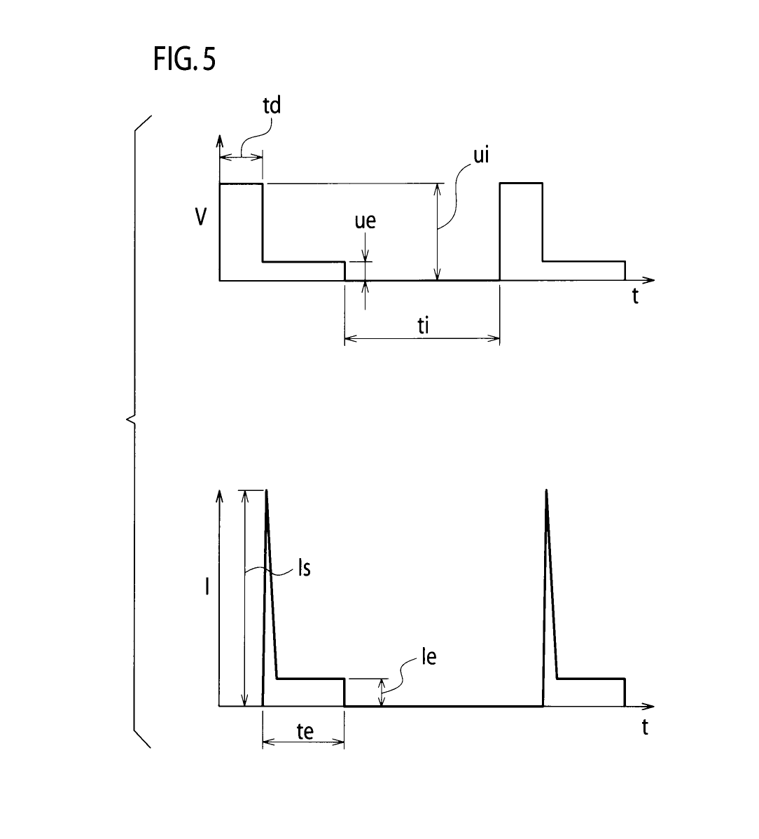

A profile of current and voltage applied from the external power source is exemplarily shown in FIG. 5 for example. Voltage V with a voltage value uᵢ is initially applied, however, electric discharge does not occur for a very short duration of time t_{d} and therefore the current I is then 0. As electric discharge next occurs, the voltage V steeply declines down to a voltage value uₑ and then current I with a steeply increased current value Iₛ flows. Subsequently current I with a steady current value Iₑ flows and then the electric discharge continues for a duration of time tₑ. Impression of the electric power is suspended for a duration of time tᵢ under proper control and next the same procedures are repeated, thereby realizing intermittent electric discharge. It can be selected that tₑ is 8 microseconds and tᵢ is 64 microseconds for example, but it is not limiting. Further it can be selected that Iₛ is 30 A, Iₑ is less than 10 A and the voltage is in the range of several tens V for example, but it is not limiting.

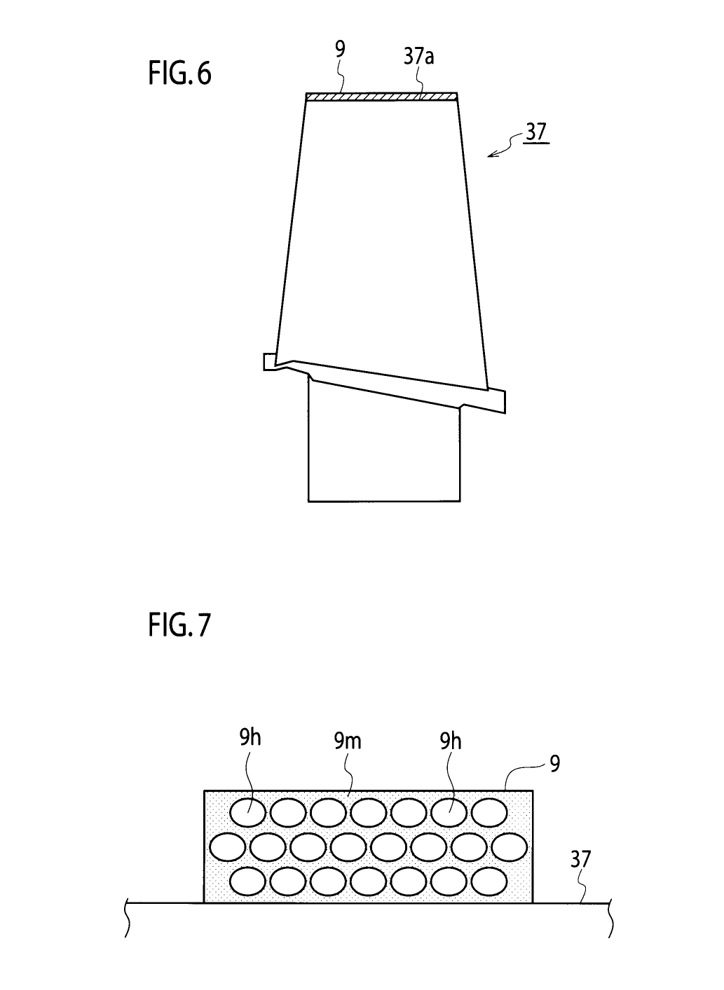

The aforementioned discharge surface treatment is applicable to growth of a titanium carbide coating 9 on an end portion 37a of a turbine rotor blade 37 shown in FIG. 6 for example. The turbine rotor blades 37 rotate with making severe friction with a turbine shroud which surrounds the blades. To protect the turbine rotor blade 37 from the friction, a hard coating such as titanium carbide is required and also the coating require considerable thickness for proving long-time use. Therefore the present embodiment is preferably applied thereto.

FIG. 7 schematically depicts a microstructure of the coating 9 according to the present embodiment. The coating 9 has a structure in which a metal phase 9m acts as a matrix and titanium carbide phases 9h disperse therein. As the metal phase 9m gives deformability to the coating, the growing coating stands local thermal shock which may occur in the course of discharge surface treatment, thereby enabling growth of a relatively thick coating. Further as the titanium carbide phase 9h gives hardness to the coating, the coating 9 stands long-time operation.

### WORKING EXAMPLE

The following tests are executed to demonstrate effects produced by the present embodiment.

With powder of titanium hydride, 1, 5, 10, 18 and 20 weight % of aluminum powder are respectively mixed, and molding and sintering are executed in a way as described above, thereby obtaining prism-shaped electrodes with a dimension of 4×10 mm, respectively. With them respectively and metal mock workpieces in oil, electric discharge is repeatedly generated with a feeding length of 2 mm of the electrodes to execute discharge surface treatment. Micro-Vickers hardness measurement is executed on the obtained coatings. Results are summarized in Table 1.

TABLE 1
Results of discharge surface treatment with titanium
hydride electrodes to which aluminum powder is added

| | Mixing ratio of aluminum powder (mass %) | | | | | |
|---|---|---|---|---|---|---|
| | 1 | 5 | 10 | 15 | 18 | 20 |
| thickness | 30 | 60 | 230 | 200 | 70 | 25 |
| (micrometers) | | | | | | |
| micro-Vickers | 1300 | 1300 | 1300 | 1300 | 1300 | 1300 |
| hardness (Hv) | or | or | or | or | or | or |
| | greater | greater | greater | greater | greater | greater |

As being apparent from Table 1, thicknesses not obtainable by conventional methods (60 micrometers or greater) are obtained if the mixing ratios of the aluminum powder are 5 weight % or greater. Further, in any range, the obtained coatings have hardness of Hv 1300 or greater.

With powder of titanium hydride, 1, 5, 10, 20, 40 and 50 weight % of nickel powder (nickel carbonyl) are respectively mixed, and molding and sintering are executed in a way as described above, thereby obtaining prism-shaped electrodes with a dimension of 4×10 mm, respectively. With them respectively and metal mock workpieces in oil, electric discharge is repeatedly generated with a feeding length of 2 mm of the electrodes to execute discharge surface treatment. Micro-Vickers hardness measurement is executed on the obtained coatings. Results are summarized in Table 2.

TABLE 2
Results of discharge surface treatment with titanium
hydride electrodes to which nickel powder is added

| | Mixing ratio of nickel powder (mass %) | | | | | |
|---|---|---|---|---|---|---|
| | 1 | 5 | 10 | 20 | 40 | 50 |
| thickness | 25 | 55 | 230 | 200 | 250 | 250 |
| (micrometers) | | | | | or | or |
| | | | | | greater | greater |
| micro-Vickers | 1300 | 1300 | 1300 | 1300 | 1300 | 800 |
| hardness (Hv) | or | or | or | or | or | or |
| | greater | greater | greater | greater | greater | less |

As being apparent from Table 2, thicknesses not obtainable by conventional methods (55 micrometers or greater) are obtained if the mixing ratios of the nickel powder are in any range of 5 weight % or greater. Further, in any range of 40 weight % or less, the obtained coatings have hardness of Hv 1300 or greater.

With powder of titanium hydride, 1, 5, 10, 20, 40 and 50 weight % of cobalt powder are respectively mixed, and molding and sintering are executed in a way as described above, thereby obtaining prism-shaped electrodes with a dimension of 4×10 mm, respectively. With them respectively and metal mock workpieces in oil, electric discharge is repeatedly generated with a feeding length of 2 mm of the electrodes to execute discharge surface treatment. Micro-Vickers hardness measurement is executed on the obtained coatings. Results are summarized in Table 3.

TABLE 3
Results of discharge surface treatment with titanium
hydride electrodes to which cobalt powder is added

| | Mixing ratio of cobalt powder (mass %) | | | | | |
|---|---|---|---|---|---|---|
| | 1 | 5 | 10 | 20 | 40 | 50 |
| thickness | 25 | 45 | 230 | 180 | 200 | 200 |
| (micrometers) | | | | | or | or |
| | | | | | greater | greater |
| micro-Vickers | 1300 | 1300 | 1300 | 1300 | 1300 | 800 |
| hardness (Hv) | or | or | or | or | or | or |
| | greater | greater | greater | greater | greater | less |

As being apparent from Table 3, thicknesses not obtainable by conventional methods (45 micrometers or greater) are obtained if the mixing ratios of the cobalt powder are in any range of 5 weight % or greater. Further, in any range of 40 weight % or less, the obtained coatings have hardness of Hv 1300 or greater.

Although detailed data are omitted, similar results are obtained in regard to iron powder as with the nickel powder or the cobalt powder. Further a case where titanium carbide is further added produces similar results.

More specifically, in the method of surface treatment of a subject body by an electric spark machine, if proper powder of aluminum or any of the iron group is mixed with powder of titanium hydride, resultant mixed powder is molded and sintered and then incorporated in the electric spark machine, and discharge surface treatment is executed in oil, a coating with sufficient thickness and hardness can be obtained. As the thickness and the hardness are sufficient, a long life coating can be expected.

Although the invention has been described above by reference to certain embodiments of the invention, the invention is not limited to the embodiments described above. Modifications and variations of the embodiments described above will occur to those skilled in the art, in light of the above teachings.

### INDUSTRIAL APPLICABILITY

A method for forming thicker coatings including titanium carbide by discharge surface treatment and electrodes therefor are provided.

1. An electrode used in combination with an electric spark machine for surface treatment, comprising:
a mixed powder including a powder of aluminum at a ratio of 5-18 weight % to the total of the mixed powder or a powder of any metal selected from the group consisting of nickel, cobalt, and iron at a ratio of 5-40 weight % to the total of the mixed powder; and
a powder of titanium hydride,
wherein the mixed powder is formed by molding and sintering into a structure so dimensioned as to be incorporated in the electric spark machine as an electrode therefor.

2. The electrode of claim 1, further comprising:
titanium carbide beyond 0 weight % and not greater than 30 weight % to the total of the mixed powder.

3. The electrode of claim 2, wherein the powder of the titanium hydride is the rest of the mixed powder.

4. A method of production of an electrode used in combination with an electric spark machine, comprising:
obtaining a mixed powder by mixing a powder of aluminum at a ratio of 5-18 weight % to the total of the mixed powder or a powder of any metal selected from the group consisting of nickel, cobalt, and iron at a ratio of 5-40 weight % to the total of the mixed powder with a powder of titanium hydride; and
molding and sintering the mixed powder to form a structure so dimensioned as to be incorporated in the electric spark machine as an electrode therefor.

5. The method of claim 4, wherein the mixed powder further includes titanium carbide beyond 0 weight % and not greater than 30 weight % to the total of the mixed powder.

6. The method of claim 5, wherein the powder of the titanium hydride is the rest of the mixed powder.

7. A method of surface treatment of a subject body by an electric spark machine, comprising:
obtaining a mixed powder by mixing a powder of aluminum at a ratio of 5-18 weight % to the total of the mixed powder or a powder of any metal selected from the group consisting of nickel, cobalt, and iron at a ratio of 5-40 weight % to the total of the mixed powder with a powder of titanium hydride;
obtaining a molded body by molding and sintering the mixed powder to form a structure so dimensioned as to be incorporated in the electric spark machine as an electrode therefor;
incorporating the molded body into the electric spark machine; and
generating a coating on the subject body by bringing the molded body close to the subject body in an oil and generating electric discharge therebetween.

8. The method of claim 7, wherein the mixed powder further includes titanium carbide beyond 0 weight % and not greater than 30 weight % to the total of the mixed powder.

9. The method of claim 8, wherein the powder of the titanium hydride is the rest of the mixed powder.
